(19) United States
(12) Patent Application Publication
(10) Pub. No.: US 2018/0172475 A1
(43) Pub. Date: Jun. 21, 2018

(54) Drive Device with Detection Apparatus and Method

(71) Applicant: FESTO AG & Co. KG, Esslingen (DE)

(72) Inventors: Jorg QUAAS, Ostfildern (DE); Manuel BRAUN, Stuttgart (DE); Franco TRAPASSO, Stuttgart (DE)

(21) Appl. No.: 15/579,795

(22) PCT Filed: Jun. 11, 2015
(86) PCT No.: PCT/EP2015/063057

§ 371 Date: Dec. 5, 2017

(51) Int. Cl. G01D 5/14; G01R 33/00; G01D 5/244; G01D 3/08

(52) U.S. Cl. CPC G01D 5/145; G01R 33/0094; G01D 3/08; G01D 5/24485; G01D 5/24461

(57) ABSTRACT

A drive device for making available a driving movement of a drive input element, which drive device includes a magnet arrangement, at least two magnetic field sensor elements which are spaced apart from one another and are designed to make available magnetic field measured values, and a detection apparatus which is designed to detect a position of the drive input element on the basis of one or more of the magnetic field measured values. The detection apparatus is designed to check the validity of the detection of position and to make available a validity signal as a function of the result of the check in accordance with at least two magnetic field measured values from at least two magnetic field sensor elements and/or in accordance with at least two position values based on the at least two magnetic field measured values and taking into account checking information which represents a reference relationship between magnetic field measured values and/or position values.

The invention relates to a drive device for providing a driving movement of a drive body, which drive body comprises a magnet arrangement, at least two magnetic field sensor elements which are spaced apart from one another and are adapted to provide magnetic field measured values, and a detection apparatus which is adapted to detect a position of the drive body on the basis of one or more of the magnetic field measured values.

The invention in particular relates to a drive device used in process technology or process automation which serves to drive via a drive body a valve body of a process valve, the valve body being mounted so as to be linearly movable, and to detect the current position of the drive body by means of the detection apparatus. In such a drive device, the drive body is for example adapted as a rod and is preferably pneumatically or electrically driven.

The invention further relates to a method in which at least two magnetic field measured values are detected by means of at least two magnetic field sensor elements which are spaced apart from one another.

A device for detecting a position of a magnet by means of a plurality of magnetic field converters is known from DE 695 10 357 T2. The converters output a plurality of output signal values corresponding to the position of the magnet. The output signal values are fitted to a curve. A conclusion is drawn on the position of the magnet relative to the arrangement of converters from the zero point of the curve.

In such a device, it may, however, occur that external interferences, such as temperature fluctuations or interfering magnetic fields influence the transformation characteristic of the field converters whereby the accuracy of the detection of position is impaired. In such a case, the device known from the prior art continues to output position values and there is no possibility to check to what extent these position values are even valid or effective. This can lead to impairment of operational safety, e.g. if actuators are actuated based on inaccurately detected or invalid position values.

The object of the invention is thus to provide a drive device of the type mentioned in the introduction by means of which increased operational safety can be ensured.

This object is achieved for a drive device of the type mentioned in the introduction with the features of claim 1. The drive device according to the invention comprises a detection apparatus which is adapted to check, in accordance with at least two magnetic field measured values from at least two magnetic field sensor elements and/or in accordance with at least two position values based on the at least two magnetic field measured values and taking into account checking information which represents a target relationship between magnetic field measured values and/or position values, the validity of the detection of position and to provide a validity signal as a function of the result of the check.

According to the invention, a piece of information—the validity signal—is consequently provided which indicates whether or not the detection of position is valid or effective. In contrast to the above-mentioned prior art, the advantage thus emerges that it can be assessed whether the position of the drive body detected by the detection apparatus is reliable and/or to what extent it corresponds to the actual position of the drive body. The provision of such a piece of information increases the operational safety since it allows any impairments of the accuracy of the detection of position to be identified and/or to introduce corresponding measures.

The probability of damage occurring due to an unnoticed detective detection of position can thereby be reduced.

According to the invention, for the validity check, magnetic field measured values or position values based thereon of magnetic field sensor elements are used, which already serve for the detection of the position of the drive body. This means that the magnetic field sensor elements already present for the detection of position are now also used for the validity check such that additional sensors do not have to be provided for the validity check according to the invention.

This has the advantage that the present invention can be implemented in an easy and cost-effective manner.

In order to check whether or not the detection of position is valid, at least two magnetic field measured values of two magnetic field sensor elements spaced apart from one another are used. Preferably, one magnetic field measured value from each magnetic field sensor element is used. In this context, a magnetic field measured value is a signal representing a location-dependent property of a magnetic field detected by a magnetic field sensor element. A magnetic field measured value can comprise one or more components—i.e. be one- or multi-dimensional—and/or comprise a scalar or a vector. A magnetic field measured value preferably comprises two magnetic field strengths in two linearly independent directions. For example, a magnetic field measured value comprises the strength of a magnetic field component along the driving movement of the drive body and the strength of a magnetic field component perpendicular to the driving movement. The direction of the driving movement is also referred to below as the axial direction and the direction perpendicular to the driving movement as the radial direction. The two magnetic field strengths can also be expressed in polar coordinates, i.e. as angle and value.

As an alternative to the two magnetic field measured values, at least two position values derived from the magnetic field measured values are used for the validity check. In this context, each value by means of which a conclusion can be drawn on a position relationship between a magnetic field sensor element and the magnet arrangement of the drive body shall be referred to as position value. The position values can for example be calculated based on a function or a value table from the magnetic field measured values.

Checking information is also taken into account for the validity check, the checking information representing a target relationship between magnetic field measured values and/or between position values. This approach is based on the assumption that in the valid state, i.e. in the state in which the detection of position takes place with the required accuracy, the magnetic field measured values and/or position values of at least two magnetic field sensor elements spaced apart from one another generally comprise a very specific relationship to one another. If, for example as is the case in the valid state, the relationship between detected magnetic field measured values and relative distance of the magnet arrangement follows a predefined regularity and the distance between two magnetic field sensor elements spaced apart from one another is fixed, the relationship of two magnetic field measured values obtained from these magnetic field sensors elements must also follow a predefined regularity in the valid state.

As a result, a conclusion can be drawn by means of a check of the relationship of magnetic field measured values of two magnetic field sensor elements spaced apart from one another whether the detection of position is valid. This predefined regularity which the two magnetic field measured values should follow in the valid state relative to one another, is referred in this context as the target relationship. The target relationship is represented by the checking information or is contained therein.

For example, the checking information defines for each first magnetic field measured value detected by a first magnetic field sensor element a determined value range in which a second magnetic field measured value of a second sensor element spaced apart from the first magnetic field sensor element must be located when the detection of position is valid. Now, if the second magnetic field measured value is not located in this value range, the detection of position is not valid and the detection apparatus outputs a corresponding validity signal.

As already described above, the validity check can also be carried out on the basis of two position values derived from the two magnetic field measured values. In this case, the checking information can, for example, define a determined value range for a first position value originating from a first magnetic field sensor element in which value range a second position value originating from a second magnetic field sensor element must be located when the detection of position is valid. As an alternative to this, the checking information can also define a determined value range in which the difference between two position values originating from two different magnetic field sensor elements must be located when the detection of position is valid.

If it is determined that the detection of position is not valid, the detection apparatus provides a corresponding validity signal. For example, the detection apparatus can output a corresponding validity signal to a different apparatus, such as an interface apparatus. Alternatively or in addition to this, the validity signal can also be provided internally in the detection apparatus and stored there, for example as a date.

The validity signal can preferably assume at least two different values, one value indicating that the detection of position is valid and the other value indicating that the detection of position is invalid.

Hall sensors can for example serve as magnetic field sensor elements. 2D or 3D Hall sensors are preferably used. 3D Hall sensors can expediently be used, the validity check then being based on only 2D magnetic field components, i.e. measured magnetic field strengths in two spatial directions. The individual magnetic field sensor elements can for example be adapted as pixel cells which are arranged in sensor cells. For example, each sensor cell comprises two or more magnetic field sensor elements.

The magnetic field sensor elements are arranged spaced apart from the drive body. The drive device preferably comprises the drive body and the drive body is displaceable along a displacement path. The magnetic field sensor elements are preferably arranged such that the distance between the magnetic field sensor elements and the magnet arrangement changes when carrying out the driving movement. The magnetic field sensor elements can expediently be arranged along an imaginary line which runs at least partly parallel to the displacement path and/or to the driving movement.

The magnet arrangement is preferably a permanent magnet fastened to the drive body. As an alternative to this, the magnet arrangement can also be embedded into the drive body or even represent the drive body. The pole direction of the magnet arrangement has a determined alignment relative to the driving movement. The magnet arrangement is in particular axially polarised such that the pole direction of the magnet arrangement is aligned parallel to the driving movement. The magnet arrangement is expediently adapted in the form of a disc, the pole direction being aligned normal to the circular base of the disc.

Advantageous further embodiments of the invention are the subject matter of the dependent claims.

In one configuration of the invention, the drive device comprises the drive body and the drive body is displaceable along a displacement path.

In a further configuration of the invention, the detection apparatus is adapted to convert a magnetic field measured value from a magnetic field sensor element into a position value using one or more initialisation parameters.

The detection apparatus is preferably adapted to convert a magnetic field measured value directly into a position value.

From the position value, which, for example, indicates the position of the magnet arrangement relative to the corresponding magnetic field sensor element, the position of the magnet arrangement can be determined, by taking into account the position of the magnet arrangement, relative to a determined reference point. In contrast, in the above-mentioned prior art, magnetic field measured values from a plurality of magnetic field sensor elements are required to determine the position of a magnet arrangement.

One or more initialisation parameters are used for the direct conversion and/or mapping of a magnetic field measured value into a position value. The initialisation parameter(s) serve in particular to describe the geometry or the spatial course of the magnetic field generated by the magnet arrangement, and/or the alignment of its magnetic field lines. The initialisation parameters preferably serve to define a relationship between the position of the magnet arrangement relative to a magnetic field sensor element and the magnetic field measured value detected by this magnetic field sensor element. The initialisation parameters can be constants which are used in a corresponding magnetic field model or a corresponding function or an algorithm. The detection apparatus preferably comprises a memory in order to store the initialisation parameters and/or the magnetic field model.

In a further configuration of the invention, the detection apparatus is adapted to determine the initialisation parameter(s) on the basis of detected magnetic field measured values.

The drive device is preferably adapted to autonomously determine the initialisation parameter(s) described above. This can preferably be carried out by measuring the magnetic field of the magnet arrangement with three magnetic field sensor elements spaced apart from one another by detecting three magnetic field measured values. On the basis of the detected magnetic field measured values, the relative distances of the magnetic field sensor elements to each other and a mathematical model, which sets the magnetic field measured values in relation to the position of the magnet arrangement, an equation system can then be established, whose solution produces the initialisation parameter(s).

If it is possible to move the magnet arrangement to a known position such as e.g. an end position, the initialisation parameters can, as an alternative to the previously-described approach, also be determined on the basis of only two detected magnetic field measured values. The determination of the initialisation parameters preferably takes place under controlled conditions, i.e. when it can for example be ensured that no external magnetic field interferes such that the detected magnetic field measured values are only based on the magnetic field of the magnet arrangement.

The magnetic field measured values indicating the greatest magnetic field strength are preferably used for determining the initialisation parameters. This increases the accuracy of the determination since in the case of these magnetic field measured values, the signal-to-noise ratio is highest, i.e. the error in the detection of position is lowest.

In a further configuration of the invention, the detection apparatus is adapted to re-determine the initialisation parameter(s) in accordance with the validity signal.

In certain cases, in particular when quasi-stationary changes to the environmental characteristics occur, the relationship between the position of the magnet arrangement and the magnetic field measured value detected by a magnetic field sensor element is changed. The initialisation parameters are then no longer suitable for determining an accurate position of the magnet arrangement on the basis of a magnetic field measured value. As already described above, this can be determined in particular by checking whether or not the relationship of two position values, which originate from different magnetic field sensor elements, correspond to a target relationship.

Now, if a deviation from the target relationship is determined, a corresponding validity signal is provided, as also described above. The detection apparatus is preferably adapted to carry out a re-determination of the initialisation parameters in this case, i.e. when the validity signal indicates that the detection of position is not valid. The re-determined initialisation parameters take into account the previously-mentioned quasi-stationary change of the environmental characteristics and are thus again suitable for determining an accurate position of the magnet arrangement on the basis of a magnetic field measured value.

The re-determination of the initial parameters is preferably dependent on a command received from an external control unit. The detection apparatus is in particular adapted to carry out the re-determination only when a corresponding command is present.

In a further configuration, the drive device is adapted to output an error signal and/or to adopt a safe state as a function of the validity signal.

The drive device is preferably adapted to output an error signal to a superordinate control unit via an interface device if the validity signal indicates that the detection of position is not valid. Alternatively or in addition thereto, the drive device can also be adapted to output an acoustic or optical warning signal in this case in order to directly warn a user of the drive device that a safe detection of position can no longer be ensured.

The drive device is preferably further adapted to adopt a safe state in the case where the detection of position is not valid. This can, for example, be carried out by the drive body moving into a predetermined position. Alternatively or in addition thereto, the force applied to the drive body can also be reduced or switched off.

In a further configuration of the invention, the detection apparatus is adapted to select at least two magnetic field measured values indicating the greatest magnetic field strength and carry out the validity check in accordance with the selected magnetic field measured values and/or in accordance with the position values which are based on the selected magnetic field measured values.

The validity check can be carried out most accurately with magnetic field measured values from the magnetic field sensor elements which are located closest to the magnet arrangement and as a result experience the strongest magnetic field. In order to use this effect, it is advantageous to select the magnetic field measured values indicating the greatest magnetic field strengths for the validity check.

Alternatively, the position values indicating the shortest distance from the magnet arrangement can also be selected for the validity check.

In a further configuration of the invention, the detection apparatus is adapted to carry out the validity check in accordance with at least two magnetic field measured values which are detected by at least two adjacent magnetic field sensor elements and/or in accordance with position values which are based on these magnetic field measured values.

In general, the target relationship between two adjacent magnetic field sensor elements can be accurately defined. This is in particular the case when the target relationship represents the distance between two magnetic field sensor elements. It is therefore advantageous to base the validity check on magnetic field measured values or position values from two adjacent magnetic field sensor elements.

In a further configuration of the invention, the detection apparatus is adapted to carry out the validity check in accordance with at least two magnetic field measured values which are detected by at least two magnetic field sensor elements adapted as pixel cells of the same sensor cell and/or in accordance with position values which are based on these magnetic field measured values.

The use of magnetic field measured values or position values of two magnetic field sensor elements adapted as pixel cells of the same sensor cell is particularly advantageous since the distance between these pixel cells is generally very accurately defined. The distance between two pixel cells of the same sensor cell, in contrast to the distance between two pixel cells of different sensor cells, in particular does not have tolerances caused by a soldering process. This is in particular the case when the two pixel cells are located on the same chip.

In a further configuration of the invention, the target relationship represents the distance between two magnetic field sensor elements or is based thereon.

The target relationship can in this case define in particular a value range in which the difference between two position values must be located in the valid state. If the individual position values each indicate the relative position of the magnet arrangement to the respective magnetic field sensor element, the difference of the position values in the valid state should approximately correspond to the distance between the associated magnetic field sensor elements. If this is not the case, the accuracy of the detection of position cannot be ensured and the detection apparatus provides a corresponding validity signal.

The previously mentioned object is further achieved by the method defined in claim 10 for the validity check of a detection of a position of a drive body which comprises a magnet arrangement, with the steps: detecting at least two magnetic field measured values by means of at least two magnetic field sensor elements spaced apart from one another, checking the validity of the detection of position in accordance with the at least two detected magnetic field measured values and/or in accordance with at least two position values based on the at least two magnetic field measured values and taking into account stored checking information which represents a target relationship between magnetic field measured values and/or position values and providing a validity signal as a function of the result of the check.

The drive body is preferably displaceable along a displacement path.

For the method, preferably the previously described drive device or the detection apparatus comprising said drive device can be used.

An exemplary embodiment of the invention is illustrated in the drawing.

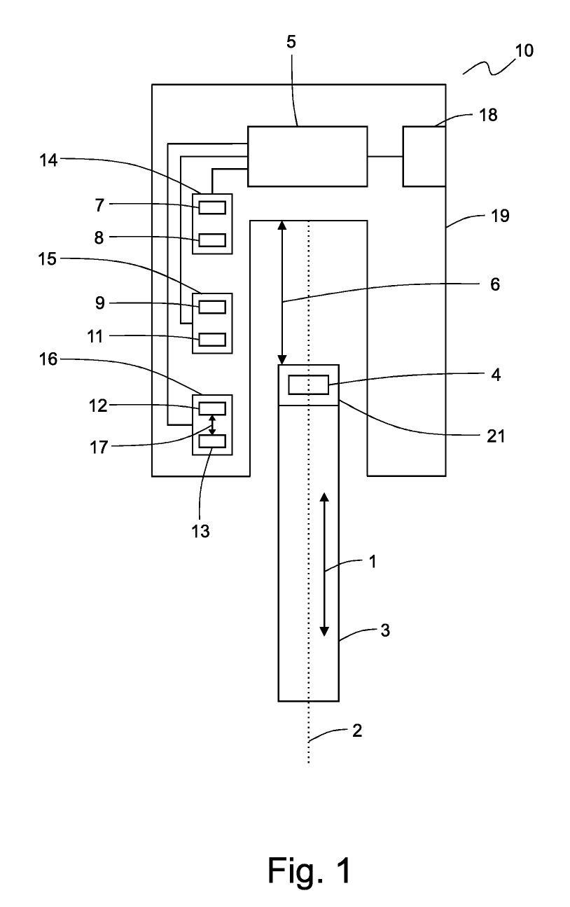

FIG. 1 shows a schematic representation of a drive device.

The drive device 10 shown in FIG. 1 represents an exemplary embodiment of the invention. The drive device 10 comprises a drive body 3, adapted for example as a piston rod of a pneumatic cylinder (not shown), as well as a device body 19 serving as a stator. The drive body 3 is displaceable along the displacement path 2 relative to the device body 19 in order to carry out the driving movement 1.

The drive body 3 comprises a magnet arrangement 4 adapted as a permanent magnet which is arranged at one end of the drive body 3. The magnet arrangement is preferably held by a magnet holder 21. The magnet arrangement 4 is expediently adapted as a pill magnet and is located compressed on the magnet holder 21 at the upper end of the drive body 3, i.e. the end of the drive body 3 facing the device body 19.

The magnet arrangement 4 is in particular arranged such that its pole direction or the magnetic field lines running through the magnet arrangement 4 are aligned parallel to the driving movement 1 and the displacement path 2.

The drive device 10 further comprises the magnetic field sensor elements 7, 8, 9, 11, 12 and 13 which are arranged spaced apart from one another on the device body 19 along an imaginary line parallel to the displacement path 2. The magnetic field sensor elements 7, 8, 9, 11, 12 and 13 are preferably adapted as 3D Hall sensors. In the exemplary embodiment shown, the magnetic field sensor elements 7, 8, 9, 11, 12 and 13 are arranged in pairs in the sensor cells 14, 15 and 16 as pixel cells. The pixel cells of the sensor cells 14, 15 and 16 have a predetermined distance 17 to each other.

The magnetic field sensor elements 7, 8, 9, 11, 12 and 13 are adapted to detect magnetic field components at least in an axial and a radial direction of the displacement path 2 and to output corresponding magnetic field measured values to the detection apparatus 5. The magnetic field measured values can also be expressed as polar coordinates, i.e. as angle and magnitude, the magnitude being the magnetic field strength and the angle representing the angle between axial and radial field or corresponding magnetic field components. The angle is preferably expressed as a value calculated with the CORDIC algorithm. The determination of the polar coordinate representation can take place in the magnetic field sensor elements 7, 8, 9, 11, 12 and 13 or the detection apparatus 5.

The detection apparatus 5 is adapted to receive the magnetic field measured values output by the magnetic field sensor elements and to determine the position 6 of the magnet arrangement 4 or the drive body 3 relative to a reference point of the device body 19 on the basis of at least one magnetic field measured value. In the example shown, the stop point of the device body 19 marked by the upper tip of the arrow 6 serves as the reference point.

In the present example, the detection apparatus 5 is adapted to detect, as the position, the displacement of the drive body 3 along the displacement path 2 relative to the reference point. This preferably occurs by means of a mathematical model or an algorithm or a value table or a function which preferably describes the spatial course of the magnetic field generated by the magnet arrangement 4 and in particular defines a relationship between a detected magnetic field measured value or its angle and a distance from a fixed reference point in space.

In the present example, the detection apparatus 5 is adapted to determine the position of the drive body 3 on the basis of a magnetic field measured value from one of the magnetic field sensor elements 7, 8, 9, 11, 12 and 13 and the following function (1):

$$x = \frac{tan ( \frac{{W}_{i}}{a} )}{b} + {c}_{i}$$

Here, Wᵢ denotes the measured angle between determined axial and radial field in a magnetic field sensor element i, a denotes a first initialisation parameter which describes the “stretching” of the magnetic field generated by the magnet arrangement 4 in the axial direction of the displacement path 2, b denotes a second initialisation parameter which describes the stretching of the magnetic field generated by the magnet arrangement 4 in a radial direction, x denotes the current position of the drive body 3 on the displacement path 2 relative to the reference point, and cᵢ denotes the distance of the magnetic field sensor element i to the reference point. The variable x can in this connection also be referred to as a position value.

In order to determine the position x, the detection apparatus 5 preferably uses the angle Wᵢ of the magnetic field measured value whose value indicates the greatest magnetic field strength.

The detection apparatus 5 is adapted to autonomously determine the previously mentioned initialisation parameters a and b in particular prior to the initial determination of a position value x. For this purpose, the detection apparatus 5 uses three magnetic field measured values from three magnetic field sensor elements spaced apart from one another. Preferably, the magnetic field measured values with the greatest value or the greatest magnetic field strength are used. In the example shown, the detection apparatus 5 would use either the magnetic field measured values of the magnetic field sensor elements 9, 11 and 12 or the magnetic field measured values of the magnetic field sensor elements 11, 12 and 13 since they have the greatest value or the greatest magnetic field strength due to their close position relative to the magnet arrangement 4.

The detection apparatus 5 is adapted to establish an equation system using the three selected magnetic field measured values, which equation system consists of three equations based on the previously shown function (1). In the equation system, the distances ci of the three magnetic field sensor elements, from which the magnetic field measured values used originate, are also used. The distances ci can be determined in advance by an optical or magnetic measurement or result for example from the chip layout. The initialisation parameters a, b and the position value x thus remain unknown in the established equation system. The established equation system comprises three equations and three unknowns and can thus be unequivocally solved in order to determine the initialisation parameters a and b. The detection apparatus 5 is adapted to use a known mathematical method such as for example Newton's iterative method to solve the equation system.

The detection apparatus 5 comprises a memory and is adapted to store the determined initialisation parameters in this memory. As an alternative to this, the detection apparatus 5 can also be adapted to store, in the memory, a mathematical function generated using the initialisation parameters or a corresponding value.

The detection apparatus 5 is further adapted to carry out a validity check of the detection of position on the basis of the magnetic field measured values detected by the magnetic field sensor elements 7, 8, 9, 11, 12 and 13. For this purpose, the detection apparatus 5 preferably applies the previously described function (1) with the determined initialisation parameters a and b to two magnetic field measured values from magnetic field sensor elements of the same sensor cell. The detection apparatus 5 is preferably adapted to select the magnetic field measured values of the sensor cell whose magnetic field sensor elements provide the magnetic field measured values with the greatest values or magnetic field strengths. In the example shown of FIG. 1, this would be, for example, the sensor cell 16 with the two magnetic field sensor elements 12 and 13 due to its close position to the magnet arrangement 4.

In the valid state, i.e. when the initialisation parameters a and b or the function (1) are suitable for describing the relationship between position of the drive body 3 and a detected magnetic field measured value or its angle, the application of the function (1) to the magnetic field measured values from two different magnetic field sensor elements should give approximately the same position of the drive body 3. The detection apparatus 5 is thus adapted to compare the difference between two obtained position values with checking information. The checking information serves here as a threshold value and represents the target relationship between the two position values. In the example described, the position values obtained should be roughly the same such that a correspondingly small value is selected here as checking information.

As an alternative to the described embodiment, it is also possible for the detection apparatus 5 to be adapted to determine the position values by means of a function different from the function (1). For example, the detection apparatus 5 can be adapted to determine the relative position between the magnet arrangement 4 and the respective magnetic field sensor element as the position value. In this case, the detection apparatus 5 is further adapted to check, in the case of the validity check, whether the difference between the two determined position values corresponds roughly to the distance between the two magnetic field sensor elements. In this case, the distance between the two magnetic field sensor elements thus serves as the target relationship represented by the checking information.

If a change of the environmental characteristics occurs after the determination of the initialisation parameters such that the application of the previously described function (1) no longer gives the actual position of the drive body 3, then the difference between the two position values will also no longer correspond to the target relationship. It can therefore be determined by means of the comparison of the two position values taking into account the checking information or the target relationship whether the detection of position is valid, i.e. whether the detection apparatus 5 is capable of determining the position of the drive body 3 with sufficient accuracy.

The accuracy of the detection of position may in particular be impaired if the magnet arrangement 4 is heated or rotated. Rotation is possible if the drive body 3 is freely rotatable and the magnetic field of the magnet arrangement 4 is inhomogeneous in the rotational direction of the drive body 3.

The detection apparatus 5 is adapted to output a validity signal as a function of the result of the validity check. The value of the validity signal depends on whether the detection apparatus 5 has considered the detection of position to be valid or invalid. In the example shown, the detection apparatus 5 is adapted to output the validity signal to the interface 18. The interface 18 is adapted to communicate with a control unit not shown here, for example a SPS, in particular via a bus system and to notify the validity state of the detection of position to said control unit.

The interface 18 is also adapted to receive commands from the control unit and transmit these to the detection apparatus 5. For example, the control unit can send a command to the interface 18 on the basis of the notified validity state which instructs a re-determination of the initialisation parameters. Upon receipt of this command, the receiver apparatus 5 carries out a determination of the initialisation parameters in the previously described manner.

1. A drive device for providing a driving movement of a drive body, which drive body comprises a magnet arrangement, the drive device comprising:
at least two magnetic field sensor elements which are spaced apart from one another and are adapted to provide magnetic field measured values; and
a detection apparatus which is adapted to detect a position of the drive body on the basis of one or more of the magnetic field measured values,
wherein the detection apparatus is adapted to check the validity of the detection of position in accordance with at least two magnetic field measured values from at least two magnetic field sensor elements which are adapted as pixel cells of the same sensor cell and/or in accordance with at least two position values based on the at least two magnetic field measured values and taking into account checking information which represents a target relationship between magnetic field measured values and/or position values, and to provide a validity signal as a function of the result of the check.

2. The drive device according to claim 1, wherein the drive device comprises the drive body and the drive body is displaceable along a displacement path.

3. The drive device according to claim 2, wherein the detection apparatus is adapted to convert a magnetic field measured value from a magnetic field element into a position value using one or more initialisation parameters.

4. The drive device according to claim 3, wherein the detection apparatus is adapted to determine at least one initialisation parameter on the basis of detected magnetic field measured values.

5. The drive device according to claim 4, wherein the detection apparatus is adapted to re-determine at least one initialisation parameter in accordance with the validity signal.

6. The drive device according to claim 1, wherein the drive device is adapted to output an error signal and/or to adopt a safe state as a function of the validity signal.

7. The drive device according to claim 1, wherein the detection apparatus is adapted to select at least two magnetic field measured values which indicate the greatest magnetic field strength and to carry out the validity check in accordance with the selected magnetic field measured values and/or in accordance with the position values which are based on the selected magnetic field measured values.

8. The drive device according to claim 1, wherein the detection apparatus is adapted to carry out the validity check in accordance with at least two magnetic field measured values, which are detected by at least two adjacent magnetic field sensor elements, and/or in accordance with position values, which are based on these magnetic field measured values.

9. (canceled)

10. The drive device according to claim 1, wherein the checking information represents the distance between two magnetic field sensor elements or is based thereon.

11. A method for checking the validity of a detection of a position of a drive body, which comprises a magnet arrangement, the method comprising:
detecting at least two magnetic field measured values by means of at least two magnetic field sensor elements spaced apart from one another;
checking the validity of the detection of position in accordance with the at least two detected magnetic field measured values and/or in accordance with at least two position values based on the at least two magnetic field measured values and taking into account stored checking information which represents a target relationship between magnetic field measured values and/or position values; and
providing a validity signal as a function of the result of the check.
